(19) United States
(12) Patent Application Publication
(10) Pub. No.: US 2009/0211798 A1
(43) Pub. Date: Aug. 27, 2009

(54) PGA TYPE WIRING BOARD AND METHOD OF MANUFACTURING THE SAME

(75) Inventors: Akio Horiuchi, Nagano (JP); Yoshikazu Hirabayashi, Nagano (JP); Yoshitaka Matsushita, Nagano (JP); Kazuhiro Oshima, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 12/372,870

(22) Filed: Feb. 18, 2009

(30) Foreign Application Priority Data
Feb. 22, 2008 (JP) 2008-041441

(51) Int. Cl. H01R 12/06; H05K 3/20

(52) U.S. Cl. 174/262; 29/831

(57) ABSTRACT

A PGA type wiring board includes a wiring board to which a head portion of a pin is joined to a pad portion with solder interposed therebetween, and a pin fixing plate having a through hole formed therein through which a shank portion of the pin is inserted, and having an adhesive layer formed on one surface thereof. The pin fixing plate is bonded to the wiring board with the adhesive layer interposed therebetween while the shank portion of the pin is inserted through the through hole. The through hole is shaped in a stepped form with a two-step configuration when viewed in cross section.

### CROSS-REFERENCE TO RELATED APPLICATIONS

This application is based on and claims priority of Japanese Patent Application No. 2008-41441 filed on Feb. 22, 2008, the entire contents of which are incorporated herein by reference.

### BACKGROUND OF THE INVENTION

(a) Field of the Invention

The present invention relates to a wiring board used for mounting an electronic component such as a semiconductor element. More particularly, it relates to a pin grid array (PGA) type wiring board and a method of manufacturing the same, the PGA type wiring board (hereinafter also referred to as a “semiconductor package” or merely a “package” for the sake of convenience) having many pins standing, to be used as external connection terminals, on a surface of the wiring board on the side opposite to the electronic component mounting surface side.

(b) Description of the Related Art

FIG. 10A shows an example of a prior art PGA type wiring board. In a PGA type wiring board 60 shown in FIG. 10A, reference numeral 61 denotes a resin substrate which constitutes a wiring board body; 62 and 63 denote wiring layers formed in desired layouts by patterning on both surfaces, respectively, of the resin substrate 61; and 64 and 65 denote protection films (insulating layers) formed to coat both surfaces exclusive of pad portions defined at desired positions of the wiring layers 62 and 63. Also, solder 66 to be connected to an electrode terminal of a chip (an electronic component) such as an IC when the chip is mounted on the wiring board 60 is deposited on the pad portion (the wiring layer 62) of the resin substrate 61 on the chip mounting surface side. A pin 68 functioning as an external connection terminal for use in mounting the wiring board 60 on a packaging board such as a motherboard is bonded by solder 67 to the pad portion (the wiring layer 63) of the resin substrate 61 on the side opposite to the chip mounting surface side.

The state of the art is such that tin-lead (Sn—Pb) based eutectic solder (e.g., solder having a composition of 62% Sn and 38% Pb, and a melting point around 183° C.) is chiefly used as the solder 66 used for connection on the IC (chip) side. On the other hand, high-temperature solder having a high lead (Pb) content (e.g., solder with a melting point around 240° C., made of Sn, Pb and antimony (Sb)), which is a kind of the Sn—Pb based solder, is used for connection of the pin 68.

Thus the reason for using a relatively high-melting solder as the solder for the pin connection while using a relatively low-melting solder as the solder for the IC connection, is to avoid melting of the solder for the pin connection during reflow soldering at the time of mounting the IC (chip) which is carried out at a stage after joining of the pin (namely, pinning) to the package substrate.

On the other hand, a changeover to the use of a relatively high-melting solder is now being carried out because of the recent trend toward lead-free, and there is also a demand for the connection to the IC to use a relatively high-melting solder (e.g., lead-free solder made of Sn, silver (Ag) and copper (Cu) and having a melting point around 220° C.) instead of the conventional relatively low-melting solder (e.g., the Sn—Pb based eutectic solder with a melting point around 183° C.). As a result, a reflow soldering temperature at the time of mounting the IC (i.e., the melting point of the solder for IC connection) is approaching the melting point of the solder for the pin.

An example of technology related to the above-mentioned prior art is disclosed in Japanese unexamined Patent Publication (JPP) (Kokai) 9-129778. This publication discloses the structure of a pin grid array (PGA) type wiring board for an electronic component. In this structure, the head of the nail head type pin is joined, by soldering or the like, to the bonding pad for the pin on the principal surface of the board. In addition, a pin fixing plate having a through hole formed to match the arrangement of the pin and capable of inserting the pins' shank therethrough and also engageable with the pins' head, is bonded to the principal surface of the board, with the pins' shank inserted through the through hole and also with the pins' head engaged therein. The structure ensures the strength of bond between the pin and the board without inserting and standing the pin in the board.

As mentioned above, the conventional technology uses solder having a higher-temperature melting point, as the solder for the pin connection, than that of the solder for the IC connection, to thereby avoid melting of the solder for the pin connection during the reflow soldering at IC assembly. On the other hand, also in the case of the connection to the IC, the changeover from the use of a low-melting eutectic solder to the use of a high-melting lead-free solder is being carried out by the influence of the trend toward lead-free, and thus, the melting point of the solder for IC connection is getting close to that of the solder for pin connection. This leads to problems as given below.

First, during the IC assembly after the pinning (i.e., the joining of the pin), the high-melting solder provided for the IC connection is melted by the reflow soldering in order to connect the pin to the electrode terminal of the chip. On this occasion, the reflow soldering temperature is close to the melting point of the solder for the pin, and thus, under the influence, a disadvantage of the solder for the pin being melted may occur. When the solder for the pin is melted, the pin arranged to stand in the regular position in the step of pinning becomes unable to maintain the position, or becomes tilted in some cases.

FIG. 10B schematically shows an example of the problem in which a shank 68b of the leftmost one of four pins 68 provided on the wiring board 60 is tilted rightward. When the pin is tilted in this manner, the position of the tip thereof is displaced from its originally designed position, which in turn causes a disadvantage in that the pin cannot be inserted into a receiving socket (namely, impairing the reliability of connection between the pin and the socket).

Also, where the solder for the pin is melted due to the influence by the reflow soldering temperature for connection of the IC, a phenomenon occurs in which the melted solder crawls up from the head to the tip of the pin (namely, undesired solder adheres to the shank of the pin). In this case, there is no particular problem when the height to which the solder crawls up stays in the vicinity of the head, but the solder may crawls up to the vicinity of the tip of the pin, depending on conditions such as the amount of solder to be used to join the pin to the pad portion, or a heating temperature.

As shown in FIG. 10B, solder 67a adhering to the shank 68b of the second pin 68 from the left remains in the vicinity of a head 68a, while solder 67b adhering to the shank 68b of the rightmost pin 68 reaches the vicinity of the tip. Where the solder adheres to the vicinity of the tip of the pin in this manner, the diameter (or thickness) of the portion of the pin with the solder becomes larger, which causes a problem in that the pin is unsuccessfully inserted into the receiving socket.

### SUMMARY OF THE INVENTION

An object of the present invention is to provide a PGA type wiring board and a method of manufacturing the same, which are capable of stably keeping a pin's standing state without the pin being in a tilted position and thereby reliably preventing a conductive material for a pin from leaking out, even if a heat treatment temperature during mounting of an electronic component after pinning exceeds the melting point of the conductive material for the pin.

According to one aspect of the invention, there is provided a PGA type wiring board including: a wiring board having a pad portion to which a head portion of a pin is joined with a conductive material interposed therebetween; and a pin fixing plate having a through hole formed therein through which a shank portion of the pin is inserted, and having an adhesive layer formed on one surface thereof. In the PGA type wiring board, the pin fixing plate is bonded to the wiring board with the adhesive layer interposed therebetween while the shank portion of the pin is inserted through the through hole.

According to the configuration of the PGA type wiring board of the present invention, the head portion of the pin joined to the pad portion of the wiring board is coated therearound with the adhesive layer, and further, the head portion and its peripheral portion are fixed by the pin fixing plate with the adhesive layer interposed therebetween. This enables eliminating a problem of the pin being tilted such as encountered in the prior art (see FIG. 103), even if, during mounting of an electronic component (such as a chip in an IC or the like) after pinning, a heat treatment temperature (e.g., a reflow soldering temperature) exceeds the melting point of the conductive material (e.g., solder) for the pin. Namely, the pin arranged to stand in a right position in the pinning step can be stably kept even during the mounting of the electronic component.

Also, a portion of the adhesive layer is filled into the gaps between the through holes in the pin fixing plate and the pins inserted therethrough, and thus the interposition of the adhesive layer enables reliably preventing the conductive material (e.g., the solder) for the pin from leaking out during the heat treatment. This enables eliminating a problem such as encountered in the prior art (see FIG. 10B) (i.e., the phenomenon in which the melted solder crawls up from the head portion to the tip, and undesired solder adheres to the shank of the pin).

According to another aspect of the invention, there is provided a method of manufacturing a PGA type wiring board, including: A method of manufacturing a PGA type wiring board, including: preparing a wiring board having pad portions to which respective head portions of pins are joined with a conductive material interposed therebetween; fabricating a pin fixing plate having through holes formed therein for inserting respective shank portions of the pins therethrough, the through holes being formed at a plurality of positions matching an arrangement of the pins; forming an adhesive layer in an uncured state on one surface of the pin fixing plate; and bonding the pin fixing plate to the wiring board, the bonding involving: disposing the wiring board and the pin fixing plate in such a manner that a surface of the wiring board on which the pins are joined faces the one surface of the pin fixing plate on which the adhesive layer is formed; bringing the facing surfaces into contact with each other while inserting the respective shank portions of the pins through the respective through holes; and curing the adhesive layer.

Description is given with reference to the following embodiments of the invention with regard to other features in configuration or process of the PGA type wiring board and the method of manufacturing the same according to the present invention, characteristic advantages based on the features thereof, and so on.

### BRIEF DESCRIPTION OF THE DRAWINGS

FIG. 1 is a sectional view schematically showing the configuration of a PGA type wiring board according to a first embodiment of the present invention;

FIGS. 2A to 2F are sectional views of various modified examples schematically showing the structures of the principal part (a pin-substrate connection portion) of the PGA type wiring board shown in FIG. 1;

FIG. 3 is a sectional view schematically showing the configuration of a PGA type wiring board according to a second embodiment of the present invention;

FIG. 4 is a sectional view schematically showing the configuration of a PGA type wiring board according to a third embodiment of the present invention;

FIG. 5 is a sectional view schematically showing the configuration of a PGA type wiring board according to a fourth embodiment of the present invention;

FIG. 6 is a sectional view schematically showing the configuration of a PGA type wiring board according to a fifth embodiment of the present invention;

FIGS. 7A to 7D are sectional views showing steps in a method of manufacturing the PGA type wiring board shown in FIG. 3;

FIGS. 8A and 8B are sectional views showing manufacturing steps following the steps shown in FIGS. 7A to 7D;

FIGS. 9A (1, 2, 3) and 9B are views for explaining other methods for “a formation process for an adhesive layer” performed in the steps shown in FIGS. 7A and 7D; and

FIGS. 10A and 10B are views for explaining problems encountered in a prior art chip mounting.

### DESCRIPTION OF THE PREFERRED EMBODIMENTS

Description is given below with regard to preferred embodiments of the present invention with reference to the accompanying drawings.

### First Embodiment

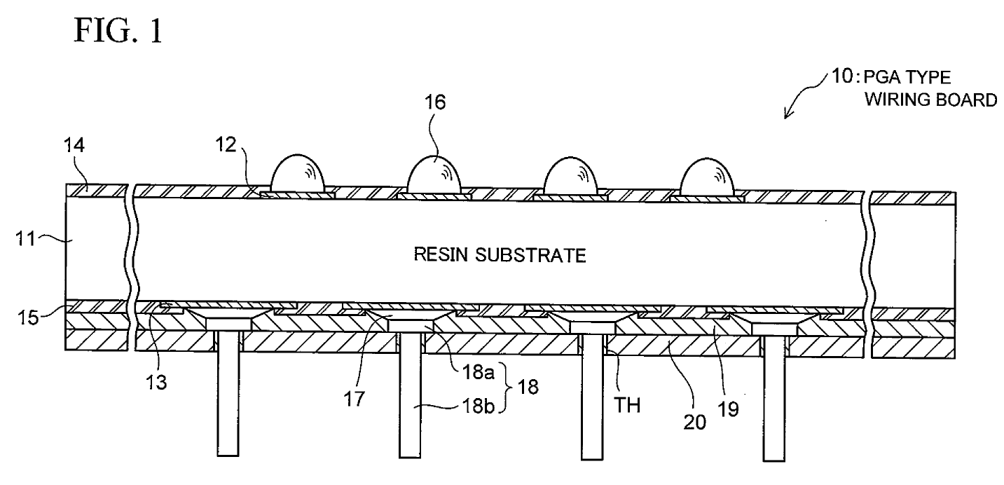

FIG. 1 shows in a sectional view the configuration of a PGA type wiring board 10 according to a first embodiment of the present invention.

In the PGA type wiring board 10, reference numeral 11 denotes a resin substrate which constitutes a wiring board body; reference numerals 12 and 13 denote wiring layers formed by patterning in desired shapes on both surfaces, respectively, of the resin substrate 11; and reference numerals 14 and 15 denote insulating layers as protection films, formed to cover both surfaces of the resin substrate 11 except pad portions defined at desired positions of the wiring layers 12 and 13, respectively.

Also, solder 16 is deposited, for instance, by presoldering, on the pad portion (the wiring layer 12) of the resin substrate 11 on the chip mounting surface side thereof, in order that a chip's electrode terminal (such as solder bump or gold (Au) bump) can be easily connected to the pad portion when mounting a chip such as an IC. Relatively high-melting lead-free solder, for example, Sn—Ag—Cu alloy with a melting point around 220° C., is used as the solder 16. Note, the provision of such solder 16 for chip connection is not necessarily required, and the pad portions may remain exposed so that the chip's electrode terminals can be connected later when needed (e.g., at a shipment destination). In this case, it is desirable that the surface of the pad portion be treated by Ni and Au plating or the like.

On the other hand, pins 18 as external connection terminals used when mounting the wiring board 10 on a packaging board such as a motherboard, are joined by solder 17 to the pad portions (the wiring layer 13) of the resin substrate 11 on the opposite side to the chip mounting surface side. Each of the pins 18 is formed of a disc-shaped or hemispherical head portion 18a, and a shank portion 18b of which one end is bonded to the head portion 18a and of which the other end forms a joining portion to a socket or the like. The pin 18 is made of, for example, Kovar (an alloy having a composition of 53% Fe, 28% Ni and 18% Co), or copper (Cu) plated with gold (Au), and its head portion 18a is joined by the solder 17 to the corresponding pad portion. Lead-free solder having the same high-melting point as the solder 16 for the chip connection, Sn—Pb based solder made of, for example, Sn, Pb and Sb (with a melting point around 240° C.), or the like, is used as the solder 17 for the pin connection.

Moreover, a pin fixing plate 20 characterizing the present invention is fixedly provided on the surface of the resin substrate 11 on the opposite side to the chip mounting surface side, with an adhesive (layer) 19 interposed therebetween. The pin fixing plate 20 has a plurality of through holes TH formed therethrough according to the arrangement of the pins 18 provided in a grid array on the mounting surface side of the resin substrate 11. The through hole TH is formed in such a size that the shank portion 18b of the pin 18 can be inserted therethrough (i.e., a slightly larger diameter than the diameter of the shank portion 18b), and also in a size smaller than the size of the head portion 18a (i.e., a smaller diameter than the diameter of the head portion 18a). Thereby, the surface of the head portion 18a to which the shank portion 18 is joined can be tightly pressed and fixed by the pin fixing plate 20. Also, the through hole TH is formed in such a size that only the shank portion 18b can be inserted therethrough, and accordingly, the adhesive 19 can be preferably prevented from crawling up.

As described later, a film-shaped or liquid adhesive in an uncured state (i.e., B-stage state) is laminated or applied to one surface of the pin fixing plate 20; the surface of the pin fixing plate 20 on which the adhesive is formed is faced to the surface of the resin substrate 11 to which the pins 18 are joined; the respective facing surfaces are brought into contact with each other by inserting the pins 18 (the shank portions 18b) through the respective through holes TH; and the adhesive is cured. Consequently, the pin fixing plate 20 can be bonded to the resin substrate 11 by the adhesive layer 19. At that time, a portion of the adhesive (layer) 19 is also filled into the gaps between the through holes TH in the pin fixing plate 20 and the pins 18 (the shank portions 18b), respectively.

Considering the function of the pin fixing plate 20, a material having insulating properties and predetermined strength and heat resistance is adequate for the pin fixing plate 20, and for example, as described later, a core material (having glass cloth as a base material and an epoxy resin, a polyimide resin or the like impregnate therein) used as a base material for a build-up wiring board can be used. Also, a metal plate such as copper (Cu), aluminum (Al), or the like, may be used. Note, when the metal plate is used, it is required that the surface of the metal plate be subjected to an appropriate insulating process. For example, when a copper (Cu) plate is used, the copper plate is coated with a resin, and when an aluminum (Al) plate or a plate of a Cu—Al alloy is used, the plate is subjected to an alumite process so as to form an insulating film. On the other hand, an adhesive commonly used in the field of semiconductor package process is adequate for a material for the adhesive 19, and for example, prepreg, a film-shaped solder resist, a film made of an epoxy resin, an acrylic resin or the like, can be used.

Incidentally, the resin substrate 11 which constitutes the wiring board body of the PGA type wiring board 10 may be in any form, as long as the wiring layer is formed at least on the outermost layer and the wiring layers are electrically connected through the inside of the substrate. In the resin substrate 11, the wiring layer may or may not be formed. In the case of the form in which the wiring layers are formed in the resin substrate 11 (this is not a member which characterizes the present invention, and thus detailed illustration thereof is omitted), the outermost wiring layers are electrically connected via the wiring layers formed within the substrate with the insulating layer interposed therebetween, and the via holes through which the wiring layers are interconnected. As an example of a substrate of this type, there is a multi-structure wiring board formed using the build-up method. On the other hand, in the case of the form in which the wiring layer is not formed in the resin substrate 11, the outermost wiring layers are electrically connected to each other via through holes formed at desired positions of in the resin substrate 11.

Description is given as appropriate with regard to the sizes (or dimensions) or the like of the members constituting the PGA type wiring board 10 according to the first embodiment, in connection with steps in a process to be described later.

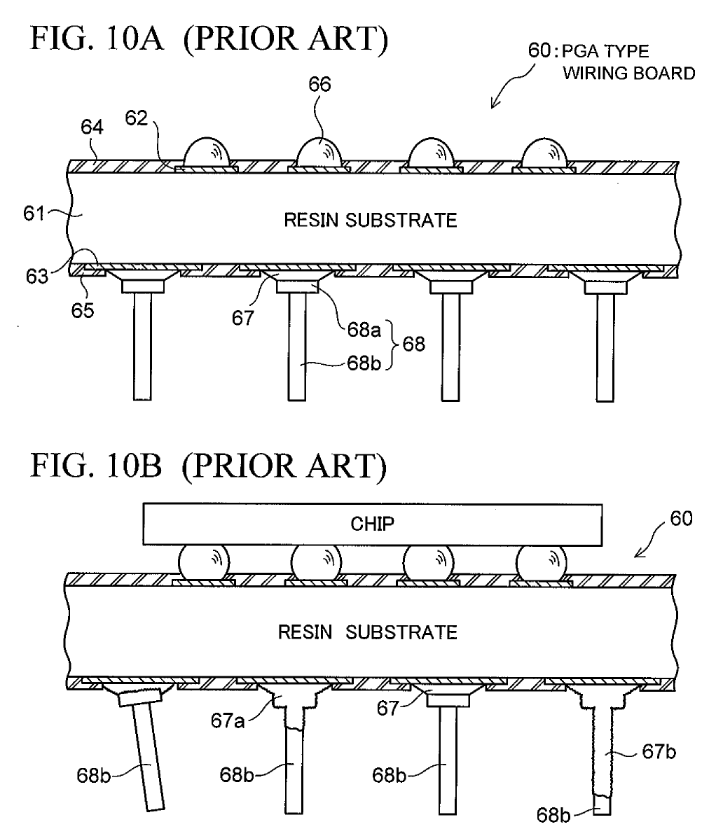

As mentioned above, according to the configuration of the PGA type wiring board (the semiconductor package) 10 of the first embodiment (see FIG. 1), the head portion 18a of the pin 18 joined to the pad portion (the wiring layer 13) of the resin substrate 11 is coated with the adhesive 19. Furthermore, the head portion 18a and a portion of the shank portion 18b in the vicinity of the head portion 18a (a pin-substrate joint portion) are fixed by the pin fixing plate 20 with the adhesive 19 interposed therebetween. This enables eliminating a problem of the tilted pin such as encountered in the prior technology (see FIG. 10B), even if the reflow soldering temperature exceeds the melting point of the solder 17 for the pin during the assembly of the chip (IC) after the pinning. In other words, the pins 18 arranged to stand in a right position in the pinning step can be stably kept even during the IC assembly, and thus, when mounting the wiring board 10 on a motherboard or the like at a later stage, the pins 18 can be reliably inserted into the respective receiving sockets (not shown). This contributes to an improvement in the reliability of connection between the pin 18 and the socket.

Also, a portion of the adhesive 19 is filled into the gaps between the through holes TH in the pin fixing plate 20 and the respective pins 18 (the respective shank portions 18b) inserted therethrough, and this interposition of the adhesive 19 in turn prevents the melted solder 17 from leaking out of the package, even if the solder 17 for the pin is melted during the reflow soldering. In other words, this structure reliably eliminates a problem such as encountered in the prior technology (see FIG. 10B) (namely, the phenomenon in which the melted solder crawls up from the head portion toward the tip of the pin, and thus an undesired solder adheres to the shank portion of the pin), and allows the pin 18 to be reliably, inserted into the socket, hence improving the reliability of connection between the pins 18 and the sockets.

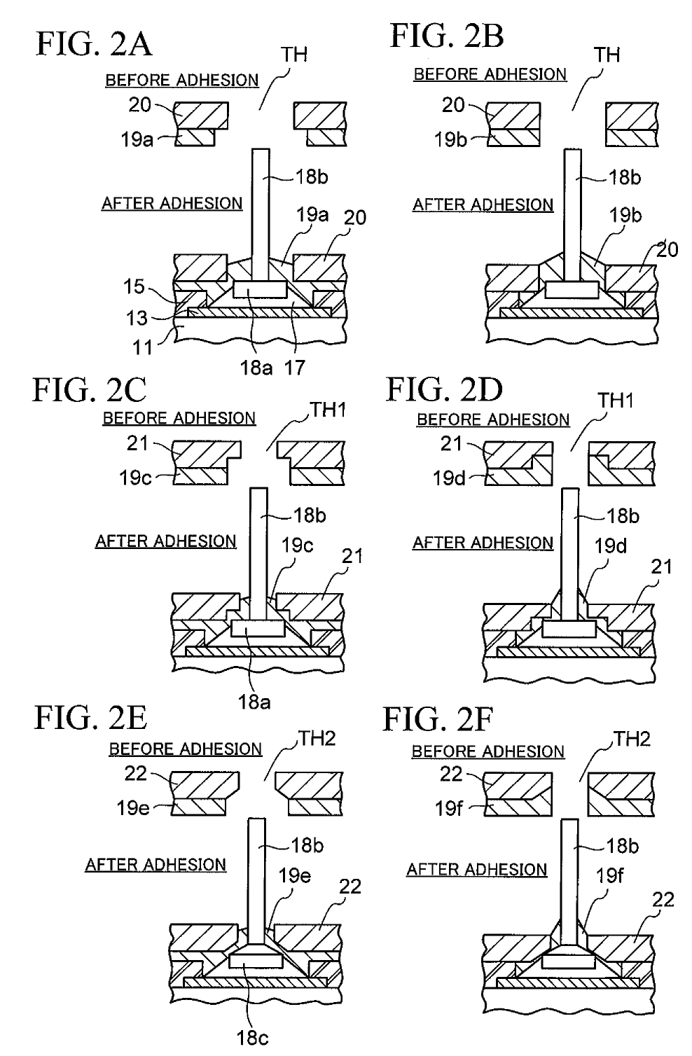

Also, as shown in FIG. 1, an exposed portion of the adhesives 19 filled into the gaps between the through holes TH in the pin fixing plate 20 and the respective pins 18 (the shank portions 18b) remains at the same level as the respective surfaces of the pin fixing plate 20. However, it is apparent that the present invention is not limited to this form. Considering the role of the adhesive (layer) 19, it is desirable that the portion (the pin-substrate joint portion) is formed in such a configuration that the adhesive 19 crawls slightly over the shank portion 18b of the pin 18. FIGS. 2A to 2F schematically show various modified examples of this configuration.

In each of FIGS. 2A to 2F, the state “before adhesion” shown in the upper part indicates the cross-sectional structure of the pin fixing plate having uncured adhesive formed on one surface thereof, before being adhered to a desired wiring board prepared in a different step (i.e., the wiring board on which the head portions of the pins are joined to the respective pad portions formed on the surface on the side opposite to the chip mounting surface side, with the solder interposed therebetween). The state “after adhesion” shown in the lower part indicates the cross-sectional structure of the pin fixing plate after the adhesion of the pin fixing plate to the wiring board.

In the illustrated example shown in FIGS. 2A and 2B, the pin fixing plate 20 is prepared by forming the through hole TH of a given size therein, and forming the adhesive on one surface of the pin fixing plate 20, provided that the adhesives are used in varying amounts as appropriate (in the illustrated example, the amount of adhesive 19h formed for the pin fixing plate 20 in FIG. 2B is larger than the amount of adhesive 19a formed for the pin fixing plate 20 shown in FIG. 2A). Then, the shank portion 18b of the pin joined to the wiring board prepared in a different step is inserted through the through hole TH in the pin fixing plate 20 having the adhesive, whereby the pin fixing plate 20 is bonded to the wiring board. Accordingly, the appropriate adjustment of the amount of adhesive 19a or 19b to be formed on the pin fixing plate 20 changes the amount (or height) of adhesive crawling up to the shank portion 18b of the pin.

In addition, when the diameter of the through hole TH in the pin fixing plate 20 is larger than the diameter of the head portion 18a of the pin so that a projecting portion of the head portion 18a (i.e., a portion of the head portion 18a projecting upwardly from the surface of the solder resist layer 15) is accommodated in the through hole TH, the height of the pin fixing plate 20 above the solder resist layer 15 can be reduced. This is effective in the point that the overall thickness of the wiring board 10 can be reduced.

In the illustrated example shown in FIGS. 2C and 2D, a pin fixing plate 21 is prepared by forming a through hole TH1 in a two-step configuration in a stepped form when viewed in cross section, and forming the adhesive on one surface of the pin fixing plate 21, provided that the adhesives are used in varying amounts as appropriate, as in the case of the above (in the illustrated example, the amount of adhesive 19d formed for the pin fixing plate 21 shown in FIG. 2D is larger than the amount of adhesive 19c formed for the pin fixing plate 21 shown in FIG. 2C). Then, the shank portion 18b of the pin joined to the wiring board prepared in a different step is inserted through the through hole TH1 in the pin fixing plate 21 having the adhesive, whereby the pin fixing plate 21 is bonded to the wiring board. In this instance, likewise, the adjustment of the amount of adhesive 19c or 19d to be formed on the pin fixing plate 21 changes the amount (or height) of adhesive crawling up to the shank portion 18b of the pin.

In addition, the through hole TH1 formed in the stepped form in the pin fixing plate 21 is such that the first step formed in the pin fixing plate 21 on the side to which the wiring board is bonded has a larger opening than the diameter of the head portion 18a of the pin, and the second step formed in the pin fixing plate 21 on the side opposite to the side to which the wiring board is bonded has an opening which is larger than the diameter of the shank portion 18b but smaller than the diameter of the head portion 18a. With this structure, the head portion 18a can be accommodated in the first step and thus the overall thickness of the wiring board can be reduced, and additionally, the second step having a smaller diameter than the head portion 18a can preferably prevent the adhesive from crawling up to the shank portion 18b.

In the illustrated example shown in FIGS. 2E and 2F, a pin fixing plate 22 is prepared by forming a through hole TH2 including a taperingly inclined portion when viewed in cross section in the pin fixing plate 22, and forming the adhesive on one surface of the pin fixing plate 22, provided that the adhesives are used in varying amounts as appropriate, as in the case of the above (in the illustrated example, the amount of adhesive 19f formed on the pin fixing plate 22 shown in FIG. 2F is larger than the amount of adhesive 19e formed on the pin fixing plate 22 shown in FIG. 2E). Then, the shank portion 18b of the pin joined to the wiring board prepared in a different step is inserted through the through hole TH2 in the pin fixing plate 22 having the adhesive, whereby the pin fixing plate 22 is bonded to the wiring board. In this instance, likewise, the adjustment of the amount of adhesive 19e or 19f to be formed on the pin fixing plate 22 changes the amount (or height) of adhesive crawling up to the shank portion 18b of the pin.

Also, the tapered through hole TH2 formed in the pin fixing plate 22 is such that the tapered portion formed in the pin fixing plate 22 on the side to which the wiring board is bonded is formed in the form of a taper having an inclined surface having a larger diameter on the bonding surface side and a smaller diameter on the side opposite to the bonding surface side. As well, the tapered portion formed in the pin fixing plate 22 on the side to which the wiring board is bonded has an opening formed in such a way to accommodate a head portion 18c of the pin, and the through hole TH2 formed in the pin fixing plate 22 on the side opposite to the side to which the wiring board is bonded has an opening which is larger than the diameter of the shank portion 18b but smaller than the diameter of the head portion 18c and is also formed in a straight form. With this structure, the head portion 18c can be accommodated in the tapered portion and thus the overall thickness of the wiring board can be reduced, and also, the straight portion having a smaller diameter than the tapered portion can preferably prevent the adhesive from crawling up to the shank portion 18b. In this event, where a surface of the head portion 18c to which the shank portion 18b is joined is formed to exhibit a tapered surface in accordance with the shape of the tapered portion of the pin fixing plate 22, the head portion 18c can be preferably pressed and fixed by the pin fixing plate 22.

As mentioned above, the amounts of the adhesives 19a to 19f to be formed on the respective pin fixing plates 20, 21 and 22 may be appropriately adjusted as needed so as to control the amounts (or heights) of the adhesives crawling up to the shank portion 18b of the pin as shown in FIGS. 2A to 2F. Note, it is required that the amount (or height) of adhesive crawling up be controlled so as to remain in the vicinity of the head portion 18a of the pin, as in the case of the crawling up of “solder” shown in FIG. 10B.

Description is given below with regard to other embodiments.

### Second Embodiment

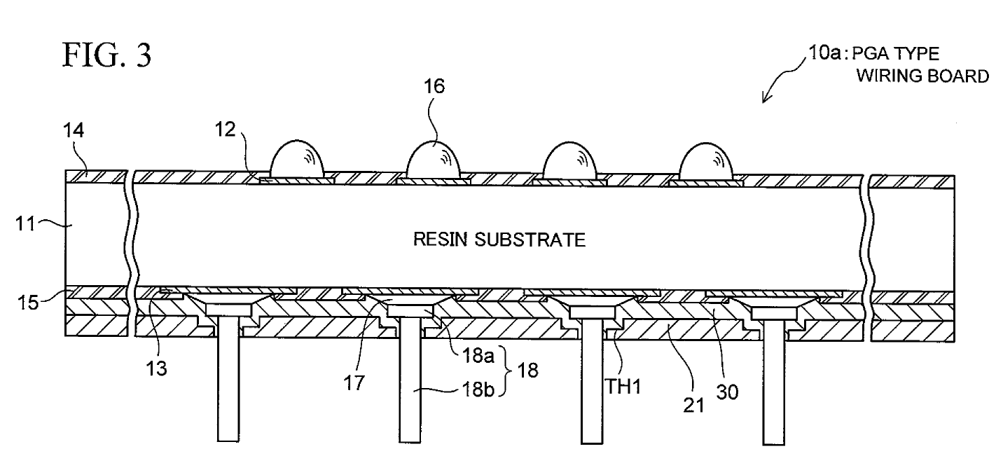

FIG. 3 shows in a sectional view the configuration of a PGA type wiring board 10a according to a second embodiment of the present invention.

The PGA type wiring board (semiconductor package) 10a according to the second embodiment is different from the PGA type wiring board 10 according to the first embodiment (FIG. 1) in the shape of the through hole TH1 for pin insertion formed in the pin fixing plate 21 and in the form of adhesion depending on the shape of the through hole TH1 (i.e., the form of an adhesive 30). Since other structural components are the same as those in the first embodiment, description thereof is omitted.

The through hole TH1 characterizing the second embodiment is formed in a stepped form in a two-step configuration when viewed in cross section. Thus, when the pin fixing plate 21 having the adhesive 30 (in an uncured state) formed thereon is bonded to the wiring board 10a, a portion of the adhesive (layer) 30 is filled into a gap between the inner wall surfaces of the stepped through holes TH1 and the respective pins 18 (the shank portion 18b). The form of this portion (i.e., the pin-substrate joint portion) corresponds to the structure shown in FIG. 2C or FIG. 2D.

According to the configuration of the PGA type wiring board 10a according to the second embodiment (FIG. 3), the following advantages can be obtained in addition to the advantageous effects obtained by the PGA type wiring board 10 according to the first embodiment (FIG. 1). Namely, the through hole TH1 formed in the pin fixing plate 21 is provided in the stepped form in the two-step configuration when viewed in cross section, and this enables relatively increasing the area of the cured adhesive layer 30 in contact with the inner wall surface of the through hole TH1. The interposition of the adhesive layer 30 having a large contact area allows further enhancement of adhesion (or strength of bond) between the pin fixing plate 21 and the head portions 18a of the pins and the portions of the shank portions 18b in the vicinity of the head portions of the pins (the pin-substrate joint portions).

Incidentally, in the second embodiment, the through hole TH1 is formed in the stepped form in the two-step configuration when viewed in cross section. However, the through hole TH2 including the taperingly inclined portion in cross section may be formed as shown in FIGS. 2E and 2F discussed above. Even if such a structure is employed, the contact area of the adhesive layer 30 can be increased as in the case of the stepped through hole TH1, and thus the like function and advantageous effects can be achieved.

### Third Embodiment

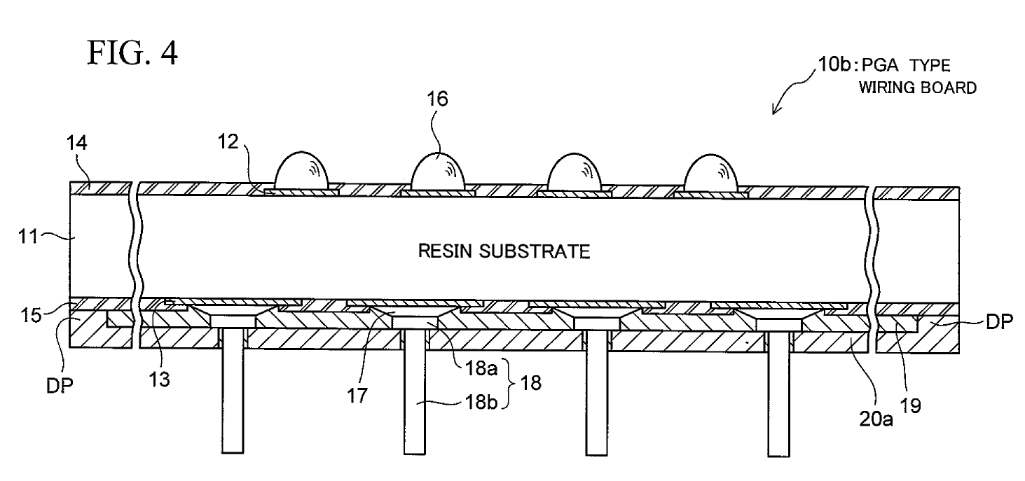

FIG. 4 shows in a sectional view the configuration of a PGA type wiring board 10b according to a third embodiment of the present invention.

The PGA type wiring board (semiconductor package) 10b according to the third embodiment is different from the PGA type wiring board 10 according to the first embodiment (FIG. 1), in that a dam portion DP (namely, a portion formed by being projected in a “dam” shape) is provided on a pin fixing plate 20a in a portion corresponding to the periphery of the package. Since other structural components are the same as those in the first embodiment, description thereof is omitted.

As described later, when the pin fixing plate having the adhesive (in an uncured state) formed thereon is bonded to the desired wiring board, a pressing or heating process or the like is performed to cure the adhesive, and a portion of the adhesive formed on the pin fixing plate may possibly flow out to the periphery of the package, depending on process conditions or the amount of adhesive used. If the adhesive flows out of the package, a product (or the package) becomes inadaptable to the external shape standard, and thus, means for coping with such a problem is necessary.

To solve this, in the third embodiment, the dam portion DP is provided in a ring-shape on the periphery of the pin fixing plate 20a, so as to prevent the adhesive from partially flowing out to the periphery of the package during the curing of the adhesive. The dam portion DP can be formed by subjecting laser processing or the like to a base material (e.g., a glass-epoxy resin substrate) constituting the pin fixing plate 20a.

### Fourth Embodiment

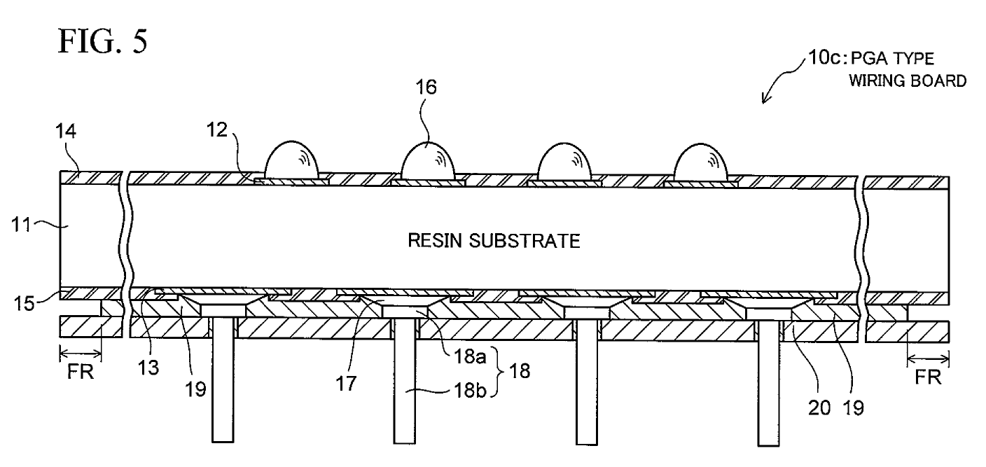

FIG. 5 shows in a sectional view the configuration of a PGA type wiring board 10c according to a fourth embodiment of the present invention.

The PGA type wiring board (semiconductor package) 10c according to the fourth embodiment is different from the PGA type wiring board 10 according to the first embodiment (FIG. 1), in that the adhesive (layer) 19 to be formed on the pin fixing plate 20 is formed in the area except the area corresponding to the periphery of the package. Namely, an area where the adhesive (layer) 19 is formed is recessed inwardly of the package by a predetermined distance (indicated by the reference FR in FIG. 5) from the end of the package, as shown in FIG. 5. The portion indicated by FR is defined as an “area where the adhesive flows out.” Since other structural components are the same as the first embodiment, description thereof will be omitted.

The PGA type wiring board 10c according to the fourth embodiment corresponds to an alternative to the PGA type wiring board 10b according to the third embodiment (FIG. 4). Namely, in the fourth embodiment, the area of the adhesive 19 formed on the pin fixing plate 20 is slightly smaller (correspondingly, the “area FR where the adhesive flows out” is provided on the periphery of the package) so that the adhesive remains in the area FR even if the adhesive partially flows out to the periphery of the package during the curing of the adhesive.

### Fifth Embodiment

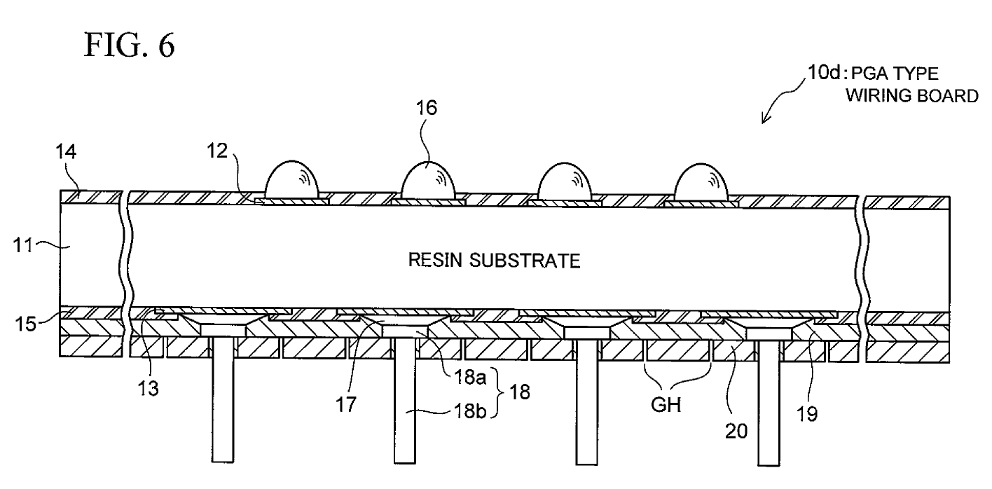

FIG. 6 shows in a sectional view the configuration of a PGA type wiring board 10d according to a fifth embodiment of the present invention.

The PGA type wiring board (semiconductor package) 10d according to the fifth embodiment is different from the PGA type wiring board 10 according to the first embodiment (FIG. 1), in that a plurality of vent holes GH are provided at desired positions in the pin fixing plate 20. Since other structural components are the same as those in the first embodiment, description thereof is omitted.

When the pin fixing plate having the adhesive in an uncured state formed thereon is bonded to the desired wiring board (during the curing), a gas originating from the adhesive may possibly produce an air gap (a void) in the adhesive layer. If such a void is produced, there arises a problem of causing deterioration in the adhesive layer (i.e., a decrease in the bond strength).

To solve this, in the fifth embodiment, the vent holes GH are appropriately provided in the pin fixing plate 20 so that the gas originating from the adhesive 19 can effectively escape to the outside. This enables preventing formation of the air gap (the void) between the pin fixing plate 20 and the wiring board (the structural members 11 to 18). The formation of such a vent hole GH can be accomplished by subjecting laser processing or the like to the base material constituting the pin fixing plate 20.

(Manufacturing Method of a PGA Type Wiring Board)

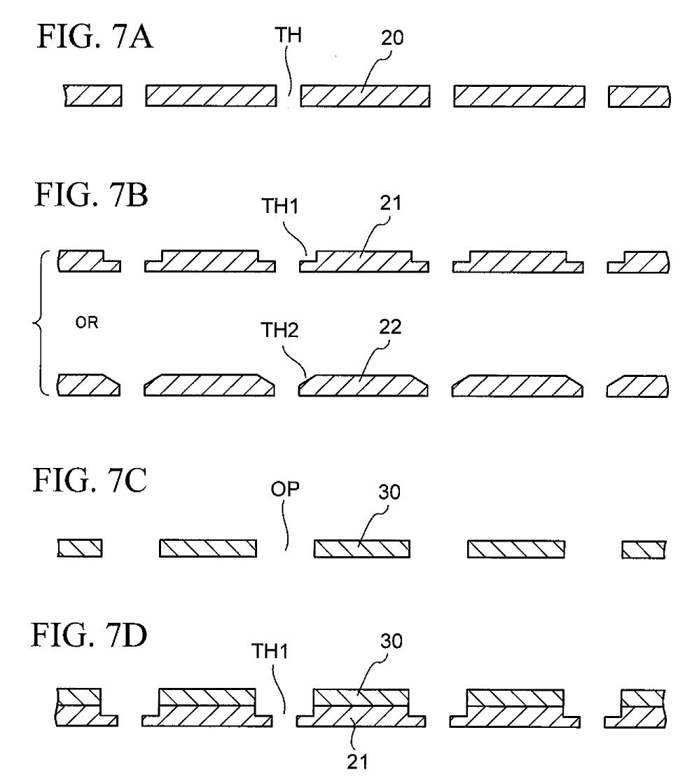

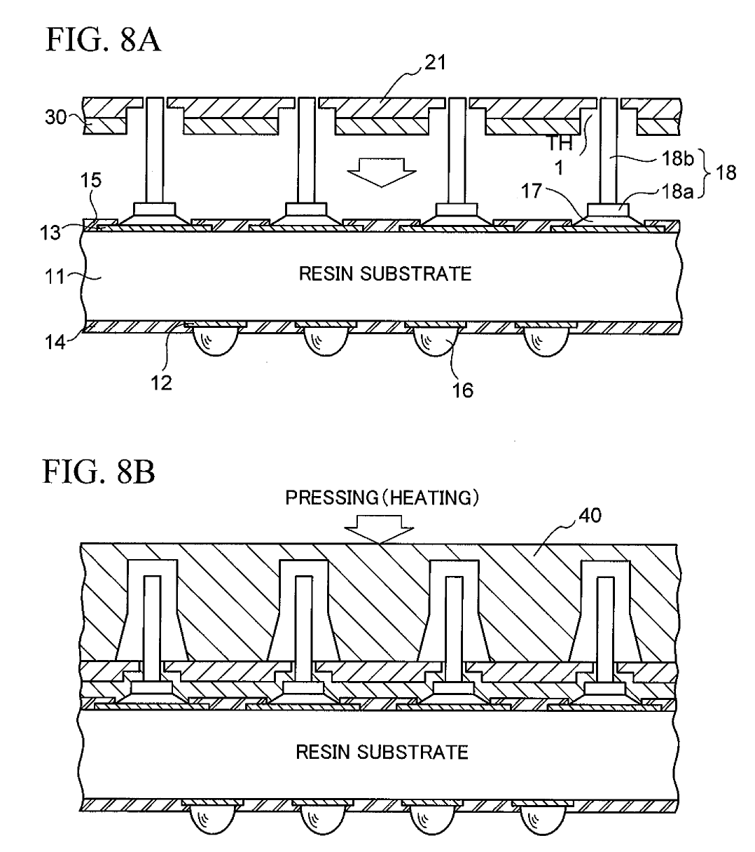

Description is given with regard to methods for manufacturing the PGA type wiring boards according to the above-mentioned embodiments. Since the basic steps in the respective manufacturing methods are substantially the same, description is given for the method of manufacturing the PGA type wiring board 10a according to the second embodiment (FIG. 3) as a typical example. FIGS. 7A to 7D and FIGS. 8A and 8B show an example of manufacturing steps.

First, there is prepared a wiring board (i.e., a structure shown in the lower part of FIG. 8A) in a stage before the bonding of the pin fixing plate (having the adhesive in an uncured state formed on one surface thereof) which characterizes the present invention. Namely, there is fabricated a wiring board including the resin substrate 11 that constitutes the wiring board body; the wiring layers 12 and 13 formed by patterning in the desired layouts on both surfaces, respectively, of the resin substrate 11; and the insulating layers 14 and 15 as the protection films, formed so as to cover both surfaces of the resin substrate except the pad portions defined at the desired positions of the wiring layers 12 and 13, respectively, in which the solder 16 is further deposited on the pad portions (the wiring layer 12) of the resin substrate 11 on the chip mounting surface side thereof, and the head portions 18a of the pins 18 are joined by the solder 17 to the pad portions (the wiring layer 13) of the resin substrate 11 on the side opposite to the chip mounting surface side.

As mentioned above, the resin substrate 11 may be in any form, as long as the wiring layer is formed at least on the outermost layer and each wiring layer is electrically connected to each other through the inside of the substrate. For example, a wiring board of a multilayer structure using build-up process may be utilized. This involves building up layers by repeating, in turn, formation of an insulating layer, formation of a via hole in the insulating layer, and formation of a wiring pattern (a wiring layer) inclusive of the inside of the via hole, on both surfaces of a core substrate used as a base material. An epoxy resin is typically used as a material for the insulating layer, and copper (Cu) is typically used as a material for the wiring layer. The outermost wiring layers 12 and 13 formed through the above process are electrically connected through the wiring layers appropriately formed in the desired locations within the substrate, and the via holes through which the wiring layers are interconnected.

Since the external connection terminals are joined to the pad portions defined at the desired positions of the outermost wiring layers 12 and 13, respectively, the wiring layers (Cu) 12 and 13 are plated with nickel (Ni) and gold (Au) in this order. This is for the purpose of improving contact bonding properties when the external connection terminals are bonded to the pad portions (i.e., the function of the Au layer), and for the purpose of enhancing adhesion between the Au layer and the Cu layer constituting each pad portion and thereby preventing Cu from diffusing into the Au layer (i.e., the function of the Ni layer). Namely, the pad portions each have a three-layer structure of Cu, Ni and Au.

Further, the solder resist layers 14 and 15 functioning as protection films are formed on the respective surfaces of the core substrate 11. The solder resist layers 14 and 15 can be formed, for example, by coating the resin substrate 11 and the wiring layers 12 and 13 with a photosensitive epoxy resin, and subjecting each resin layer thus obtained to patterning in desired layouts (i.e., the layouts exclusive of the pad portions of the respective wiring layers 12 and 13). Further, the solder 16 is deposited by presoldering on the pad portions (the wiring layer 12) of the resin substrate 11 on the chip mounting surface side thereof, and the pins 18 are joined by means of the solder 17 to the pad portions (the wiring layer 13) of the resin substrate 11 on the side opposite to the chip mounting surface side. The joining of the pins 18 is performed by coating the pad portions with solder paste, bringing the head portions 18a of the pins 18 into contact with the respective pad portions, and performing reflow soldering with the pins 18 standing in a right position.

Under the condition where the wiring board in the stage before bonding the pin fixing plate thereto is prepared in this manner, the process goes to the manufacturing steps.

First, in the first step (FIG. 7A), a glass-epoxy resin substrate having, for example, a size of around 10 mm×10 mm to 70 mm×70 mm and a thickness around 10 to 800 μm (e.g., a core material used as a base material for a build-up wiring board) is prepared as the base material constituting the pin fixing plate 21 (FIG. 3). Then, the through holes TH (whose diameter is about 1.1 to 1.5 times the diameter of the pin 18) for inserting the pins 18 (the shank portions 18b) therethrough are formed at desired positions in the substrate so as to match the arrangement of the pins 18 provided on the mounting surface side of the resin substrate 11. For example, mechanical drilling, a laser beam process using a CO₂, laser, an excimer laser or the like, pressing using a cutting die, or the like may be used to form the through holes TH. Furthermore, where a metal plate such as copper (Cu) or aluminum (Al) (whose surface is subjected to an insulating process) is used as the base material, etching process may be used to form the through holes TH. The base material is subjected to a hole formation process in this manner, which in turn leads to the fabrication of the pin fixing plate 20 having the through holes TH of a given size formed therein as shown in FIG. 7A.

Incidentally, in the case of the PGA type wiring board 10b according to the third embodiment (see FIG. 4), in this step, the dam portion DP can be formed at the position corresponding to the periphery of the package. Also, in the case of the PGA type wiring board 10d according to the fifth embodiment (FIG. 6), in this step, the vent holes GH can be formed at the desired positions in the pin fixing plate 20.

In the next step (FIG. 7B), openings each having a larger diameter than the diameter of the through hole TH (e.g., the diameter of the opening is about 1.1 to 1.5 times that of the pin 18) are further formed midway in the through holes TH in the fabricated pin fixing plate 20 (e.g., to a depth of about one-half that of the through hole TH). Namely, the through holes TH1 (FIG. 3) are formed in the stepped form in the two-step configuration when viewed in cross section. For example, mechanical drilling, milling or the like may be used for the additional hole formation process. Also, where a metal plate is used as the base material, etching process may be used to form the openings. The additional hole formation process is performed in this manner, which in turn leads to the fabrication of the pin fixing plate 21 having the through holes TH1 formed therein as shown in FIG. 7B.

Alternatively, as a modified example of the additional hole formation process (i.e., the stepped through holes TH1), the through hole TH2 (the pin fixing plate 22) may be formed so as to include a taperingly inclined portion when viewed in cross section. Also in this instance, the same process as the above can be used to form the openings.

In the next step (FIG. 7C), the adhesive (layer) 30 to be applied to the pin fixing plate 21 is prepared. First, the adhesive 30 in film form (of about 5 to 300 μm thick), made of an epoxy resin, an acrylic resin or the like in an uncured state (B-stage state), is prepared as the material constituting the adhesive layer 30. Then, openings OP are formed in the adhesive 30 in film form so as to match the arrangement of the through holes TH1 formed in the pin fixing plate 21 (i.e., the arrangement of the pins 18). The size of the opening OP is selected, at least, to the larger diameter (the upper one in the illustrated example) of the through hole TH1 formed in the pin fixing plate 21. For example, mechanical drilling, a laser beam process, pressing using a cutting die, or the like may be used to form the openings OP.

In the next step (FIG. 7D), the adhesive (layer) 30 is tacked on one surface of the pin fixing plate 21 having the through holes TH1 formed therein (i.e., on the surface on the side on which the through holes TH1 have the larger diameter), while the positions of the openings OP are aligned with the positions of the through holes TH1. In this event, tacking takes place at a lower temperature (around 50 to 110° C.) than the curing temperature (around 120 to 180° C.) of the adhesive 30.

In the next step (FIG. 5A), the surface of the pin fixing plate 21 on the side thereof on which the adhesive 30 (in the uncured state) is applied is faced to the surface of the wiring board prepared in advance in a different step from this step (i.e., the structure shown in the lower part of FIG. 8A the structural members 11 to 18) on the side thereof to which the pins 18 are joined, and the shank portions 18b of the pins 18 are inserted through the corresponding through holes TH1, respectively, and thereby, the respective facing surfaces are brought into contact with each other.

In the next step (FIG. 8B), the pin fixing plate 21 (the adhesive layer 30 in uncured state) and the wiring board 10a in contact with each other at the facing surfaces are pressed by a press 40 and are further heated to a temperature around 20 to 180° C. so that the pin fixing plate 21 and the wiring board 10a are bonded together. During the heating, the adhesive layer 30 is cured, coats the head portions 18a of the pins 18 as shown in FIG. 8B, and is further filled into the gaps between the through holes TH1 in the pin fixing plate 21 and the respective shank portions 18b of the pins 18.

The above steps lead to the manufacture of the PGA type wiring board 10a according to the second embodiment (FIG. 3).

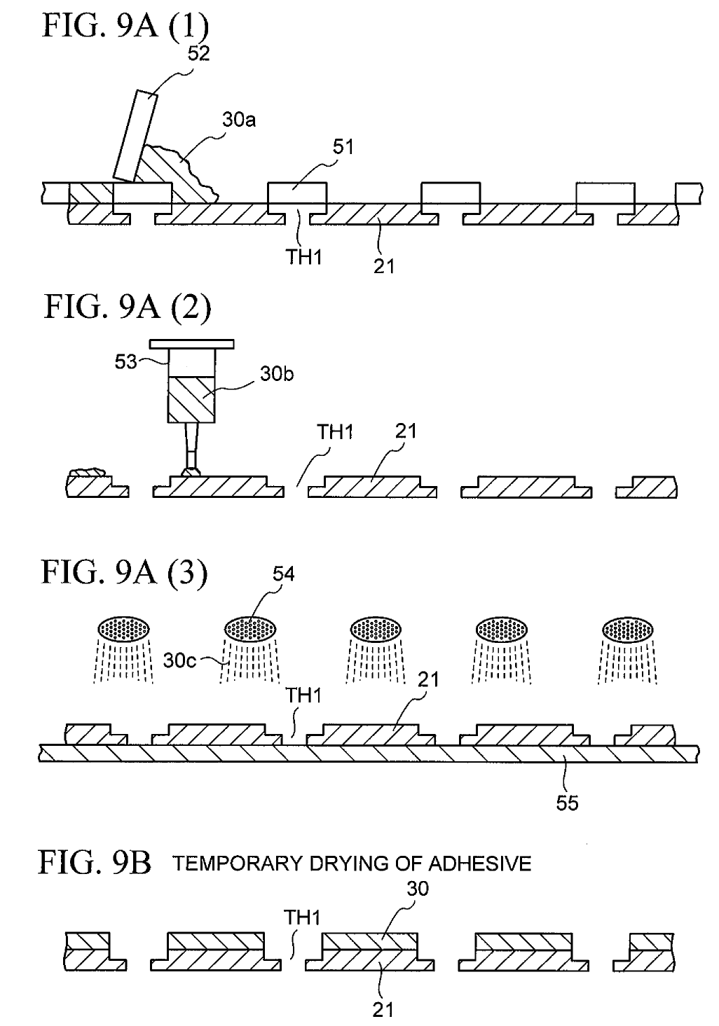

The above-mentioned process has been described by taking the example where the resin in film form is used to form the adhesive layer 30. However, it is apparent that the material for use is not limited to the material in film form. A liquid (or paste) resin can also be used. FIGS. 9A and 9B show several methods in simplified form which are employed in this instance.

The basic process involves, first, applying a liquid or paste resin (such as an epoxy resin or an acrylic resin) to one surface of the pin fixing plate 21 having the through holes TH1 formed at the desired positions therein, by any one of methods shown in FIGS. 9A(1) to 9A(3); and then temporarily drying the applied resin (i.e., the adhesive 130) as shown in FIG. 9B. In this event, the temporary drying takes place at a lower temperature than the curing temperature of the adhesive 30. Thereby, the equivalent structure to that shown in FIG. 7D is formed.

In the illustrated example shown in FIG. 9A(1), a screen printing method is used to apply the resin. Specifically, a mask 51 formed by patterning so as to hide the arrangement of the pins 18 (i.e., the portions corresponding to the through holes TH1) in accordance with the arrangement of the pins 18 provided on the resin substrate 11, is placed on the pin fixing plate 21, and resin paste 30a is squeezed into the openings of the mask 51 using a squeegee 52 to thereby coat the pin fixing plate 21. Also, in the illustrated example shown in FIG. 9A(2), a dispenser 53 containing a liquid resin (i.e., an adhesive 30b) is used to dispense the appropriate amount of adhesive 30b through its nozzle onto the pin fixing plate 21 so that a coating of the adhesive 30b is applied thereto. Also, in the illustrated example shown in FIG. 9A(3), a shower 54 is used to spray a liquid resin (adhesive 30c) onto the pin fixing plate 21 so that the adhesive 30c is applied thereto. In this instance, the resin is sprayed in mist form, and thus, a protective sheet 55 is laminated on the surface of the pin fixing plate 21 opposite to the target surface and the lateral side, which in turn prevents undesired resin from adhering thereto.

In the above-mentioned embodiments, description has been given by taking the case where the resin substrate 11 is used as the form of the wiring board in the stage before the bonding of the pin fixing plate (having the adhesive in uncured state formed on one surface thereof) which characterizes the present invention. However, of course, it should be understood that the form of the wiring board is not limited to the resin substrate, as is also apparent from the gist of the present invention. For example, the wiring board may be in the form of a silicon substrate such as used in CSP (chip size package). In the case of this form, electrode pads of aluminum (Al), in place of the pad portions defined at the desired positions of the wiring layers 12 and 13, are provided on the silicon (Si) substrate, and passivation films made of SiO₂, SiN, a polyimide resin or the like, are provided in place of the solder resist layers 14 and 15.

What is claimed is:

1. A PGA type wiring board comprising:
a wiring board having a pad portion to which a head portion of a pin is joined with a conductive material interposed therebetween; and
a pin fixing plate having a through hole formed therein through which a shank portion of the pin is inserted, and having an adhesive layer formed on one surface thereof, wherein
the pin fixing plate is bonded to the wiring board with the adhesive layer interposed therebetween while the shank portion of the pin is inserted through the through hole.

2. The PGA type wiring board according to claim 1, wherein the through hole is shaped in a stepped form with a two-step configuration when viewed in cross section.

3. The PGA type wiring board according to claim 1, wherein the through hole is shaped to include a taperingly inclined portion when viewed in cross section.

4. A method of manufacturing a PGA type wiring board, comprising:
preparing a wiring board having pad portions to which respective head portions of pins are joined with a conductive material interposed therebetween;
fabricating a pin fixing plate having through holes formed therein for inserting respective shank portions of the pins therethrough, the through holes being formed at a plurality of positions matching an arrangement of the pins;
forming an adhesive layer in an uncured state on one surface of the pin fixing plate; and
bonding the pin fixing plate to the wiring board, the bonding involving:
disposing the wiring board and the pin fixing plate in such a manner that a surface of the wiring board on which the pins are joined faces the one surface of the pin fixing plate on which the adhesive layer is formed;
bringing the facing surfaces into contact with each other while inserting the respective shank portions of the pins through the respective through holes; and
curing the adhesive layer.

5. The method of manufacturing a PGA type wiring board, according to claim 4, wherein the fabrication of the pin fixing plate includes:
forming through holes with a given diameter at positions matching the arrangement of the pins; and
forming an opening having a larger diameter than the through hole, the opening extending along the through hole to a middle thereof.

6. The method of manufacturing a PGA type wiring board, according to claim 4, wherein when the pin fixing plate is fabricated, a dam-shaped projected portion is formed at a position corresponding to a periphery of the pin fixing plate.

7. The method of manufacturing a PGA type wiring board, according to claim 4, wherein when the pin fixing plate is fabricated, a vent hole is formed at a desired position of the pin fixing plate.

8. The method of manufacturing a PGA type wiring board, according to claim 4, wherein when the adhesive layer is formed, the adhesive layer is formed exclusive of a region of a periphery of the pin fixing plate.
